(19) United States
(12) Patent Application Publication
(10) Pub. No.: US 2008/0283994 A1
(43) Pub. Date: Nov. 20, 2008

(54) Stacked package structure and fabrication method thereof

(75) Inventors: Ho-Yi Tsai, Taichung Hsien (TW); Chien-Ping Huang, Taichung (TW); Jung-Pin Huang, Taichung Hsien (TW); Chin-Huang Chang, Taichung Hsien (TW); Cheng-Hsu Hsiao, Taichung (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/152,687

(22) Filed: May 16, 2008

(30) Foreign Application Priority Data
May 18, 2007 (TW) 096117702

(51) Int. Cl. H01L 23/49; H01L 21/56

(52) U.S. Cl. 257/686; 438/109; 257/E23.024; 257/E21.502

(57) ABSTRACT

A stacked package structure and fabrication method thereof are disclosed, including providing a substrate having a plurality of stackable solder pads formed on surface thereof for allowing at least one semiconductor chip to be electrically connected to the substrate; forming an encapsulant for encapsulating the semiconductor chip and further exposing the stackable solder pads from the encapsulant, thus forming a lower-layer semiconductor package; forming conductive bumps on at least one stackable solder pad by means of wire bonding such that at least one upper-layer semiconductor package can be mounted via solder balls on the conductive bumps and the stackable solder pads of the lower-layer semiconductor package to form a stacked package structure, wherein, stacking height of the solder balls and the conductive bumps is greater than height of the encapsulant of the lower-layer semiconductor package, thus, when stacking fine pitch semiconductor packages or when warps occur to the upper-layer semiconductor package or the lower-layer semiconductor package, the conductive bumps can compensate for inadequate height caused by solder ball collapse or fill up gaps between the solder balls and the stackable solder pads caused by warps, thereby allowing the solder balls to be able to effectively contact and wet on the substrate of the lower-layer semiconductor package.

### BACKGROUND OF THE INVENTION

1. Field of the Invention

The invention generally relates to a semiconductor package technique, and more specifically to a stacked package structure and fabrication method thereof.

2. Description of Related Art

The development of electronic products of nowadays is in a trend of multiple functions, high electricity and high operational speed. To conform with the development trend, the semiconductor industry aggressively focuses on developing semiconductor devices integrating a plurality of chips or packages, thereby meeting demands of electronic products.

Please referring to FIG. 1, a stacked package structure is disclosed by U.S. Pat. No. 5,222,014, which comprises a ball grid array (BGA) substrate 11 with a plurality of solder pads 110 disposed on an upper surface thereof, a semiconductor chip 10 mounted on the substrate 11 and an encapsulant 13 formed to encapsulate the semiconductor chip 10 so as to obtain a first semiconductor package 101. Then, a second semiconductor package 102 is mounted on and electrically connected to the solder pads 110 of the substrate 11 of the first semiconductor package 101 via solder balls 14 with a reflow process, thus forming a stacked package structure.

However, in the abovementioned stacked package structure, in order to make the second semiconductor package 102 be effectively mounted on the first semiconductor package 101 via the solder balls, height of the encapsulant 13 of the first semiconductor package 101 must be well-controlled. When pitch of the traditional solder balls 14 is 1 mm, the solder balls have a diameter of c.a. 0.5 mm, and during reflowing the solder balls 14 to the substrate 11, the solder balls 14 collapses to a height of 0.4 mm, therefore, the height of the encapsulant 13 of the first semiconductor package 101 is preferably not higher than 0.3 mm.

However, in order to enhance electrical performance of the package structure and apply the package structure in fine pitch packages, the pitch between solder balls must be reduced to 0.65 mm or 0.5 mm, and diameter of the solder balls must be reduced to 0.3 mm. Accordingly, the solder balls will collapse to c.a. 0.24 mm after a reflowing process, which is definitely smaller than height of the encapsulant of the first semiconductor package. Therefore, the second semiconductor package cannot effectively make contact and wet on the substrate of the first semiconductor package via the solder balls, thereby leading to failure of electrical connection therebetween.

In addition, warps that occur to the substrate of the first or the second semiconductor package due to processing stress will produce gaps between periphery of the substrate of the first semiconductor package and the solder balls of the second semiconductor package, which can lead to poor wetting and make it difficult to form effective solder joints between the solder balls and the solder pads of the substrate.

In view of the foregoing drawbacks, another stacked package structure is disclosed by U.S. Pat. No. 6,987,314. Please referring to FIG. 2, a pre-solder material 22 is pre-disposed on the solder pads of the substrate of a first semiconductor package 201 such that a second semiconductor package 202 can be mounted and reflowed onto the pre-solder material 22 via solder balls 24, thereby positioning the second semiconductor package 202 on the first semiconductor package 201.

However, according to the method of the U.S. Pat. No. 6,987,314, since the pre-solder material must be predisposed on the solder pads of the substrate of the first semiconductor package, not only the fabrication cost is increased but also the fabrication process is complicated. Furthermore, during the encapsulation molding process of the first semiconductor package for forming the encapsulant to encapsulate the chip, since surface of the substrate has the predisposed pre-solder material, it may cause poor holding of the encapsulation mold, or the pre-solder material may be damaged by the encapsulation mold. In addition, if the pre-solder material is disposed after the chip encapsulation molding process, an additional reflow process is required, thereby further increasing the fabrication cost.

In view of the above, it has become urgent to provide a stacked package structure and fabrication method thereof, which can avoid ineffective contact and wet of the solder balls of an upper-layer semiconductor package on the substrate of a lower-layer semiconductor package due to insufficient height of the solder balls of fine pitch semiconductor packages or warps of the substrates when stacking and electrically connecting the upper-layer semiconductor package to the lower-layer semiconductor package via solder balls, and can also avoid high fabrication cost and complicated fabrication process due to pre-solder material applied on the solder pads of the substrate of a lower-layer semiconductor package, as well as avoid poor holding of encapsulation mold and damage of pre-solder material by encapsulation mold.

### SUMMARY OF THE INVENTION

In view of the disadvantages of the prior art mentioned above, it is an objective of the present invention to provide a stacked package structure and fabrication method thereof, which is applicable to stacked fine pitch semiconductor packages.

It is another objective of the present invention to provide a stacked package structure and fabrication method of, which is capable of avoiding ineffective contact and wet of the solder balls of an upper-layer semiconductor package on the substrate of a lower-layer semiconductor package due to insufficient height of the solder balls of fine pitch semiconductor packages or warps of the substrates of semiconductor packages when stacking and electrically connecting the upper-layer semiconductor package to the lower-layer semiconductor package via solder balls.

It is a further objective of the present invention to provide a stacked package structure and fabrication method thereof, which is applicable to stacked fine pitch semiconductor packages without the need of applying pre-solder material.

It is still another objective of the present invention to provide a stacked package structure and fabrication method thereof, which is capable of avoiding high fabrication cost and complicated fabrication process caused by disposing of the pre-solder material in the prior art.

To achieve the aforementioned and other objectives, the present invention provides a fabrication method of a stacked package structure, which comprises: providing a substrate with a plurality of stackable solder pads on surface thereof, electrically connecting at least one semiconductor chip to the substrate, and forming an encapsulant to encapsulate the semiconductor chip with the stackable solder pads exposed from the encapsulant, thus forming a lower-layer semiconductor package; forming conductive bumps on at least one stackable solder pad by means of wire bonding; and providing at least one upper-layer semiconductor package, and mounting the upper-layer semiconductor package on the conductive bumps and the stackable solder pads of the lower-layer semiconductor package via solder balls so as to form a stacked package structure, wherein, stacking height of the solder balls and the conductive bumps is greater than height of the encapsulant of the lower-layer semiconductor package.

Accordingly, the present invention also provides a stacked package structure, which comprises: a lower-layer semiconductor package comprising a substrate, a semiconductor chip electrically connected to the substrate, an encapsulant formed on the substrate for encapsulating the semiconductor chip, and a plurality of stackable solder pads formed on surface of the substrate and exposed from the encapsulant; conductive bumps formed on at least one stackable solder pad by means of wire bonding; and at least one upper-layer semiconductor package mounted on the conductive bumps and the stackable solder pads via solder balls, wherein, stacking height of the solder balls and the conductive bumps is greater than height of the encapsulant of the lower-layer semiconductor package.

In one embodiment of the present invention, when the upper-layer semiconductor package is a fine pitch semiconductor package and height of the solder balls of the upper-layer semiconductor package after collapse is smaller than height of the encapsulant of the lower-layer semiconductor package, the conductive bumps are disposed on all of the stackable solder pads of the substrate of the lower-layer semiconductor package such that when the upper-layer semiconductor package is mounted on the lower-layer semiconductor package via the solder balls, the conductive bumps can compensate for the insufficient height due to collapse of the solder balls. Thus, the solder balls can effectively contact and wet on the substrate of the lower-level semiconductor package.

In another embodiment of the present invention, when warps occur to the upper-layer and the lower-layer semiconductor packages due to processing stress, the conductive bumps can be selectively disposed on the stackable solder pads at periphery of the substrate so as to fill up gaps between the solder balls and the stackable solder pads at periphery of the upper-layer and the lower-layer semiconductor packages generated by warps. Thus, the solder balls can effectively contact and wet on the substrate of the lower-layer semiconductor package.

In addition, the conductive bumps are gold stud bumps formed by wire bonding using a wire bonding machine, and one single conductive bump or a plurality of conductive bumps in a plane or vertically stacked configuration can be disposed on one stackable solder pad.

According to the present invention, the conductive bumps are formed on at least one stackable solder pad on surface of the substrate of a lower-layer semiconductor package such that when the upper-layer and the lower-layer semiconductor packages are combined through solder balls, the conductive bumps can compensate for insufficient height caused by solder ball collapse or fill up gaps between the solder balls and the stackable solder pads of the substrate at periphery of the upper-layer and the lower-layer semiconductor packages caused by warps, thereby preventing the conventional problem of poor soldering connection. Meanwhile, the present invention overcomes the conventional drawbacks of high fabrication cost and complicated fabrication process caused by predisposing of a pre-solder material.

### BRIEF DESCRIPTION OF DRAWINGS

The present invention can be more fully understood by reading the following detailed description of the preferred embodiments, with reference made to the accompanying drawings, wherein:

FIG. 1 is a sectional view diagram of a stacked package structure disclosed by U.S. Pat. No. 5,222,014;

FIG. 2 is a sectional view diagram of a stacked package structure disclosed by U.S. Pat. No. 6,987,314;

FIGS. 3A through 3D are sectional view diagrams of a stacked package structure and fabrication method thereof according to a first embodiment of the present invention;

FIGS. 4A through 4C are sectional view diagrams of a stacked package structure and fabrication method thereof according to a second embodiment of the present invention; and

FIGS. 5A through 5C are sectional view diagrams illustrating variation in the number and arrangement of the conductive bumps in different embodiments of the present invention.

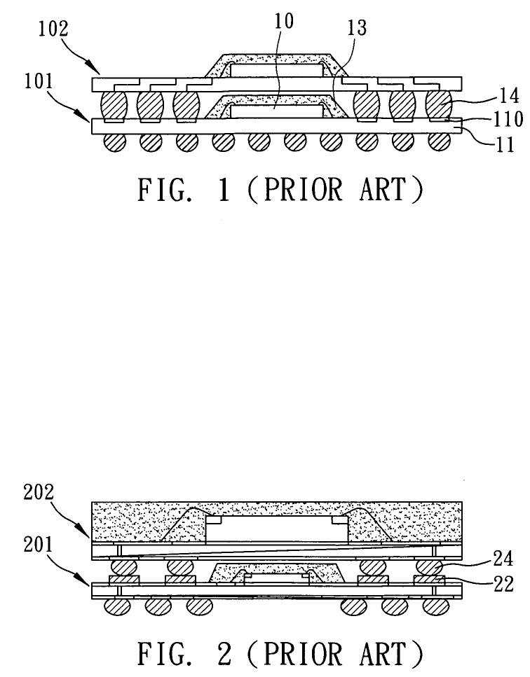

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

### First Embodiment

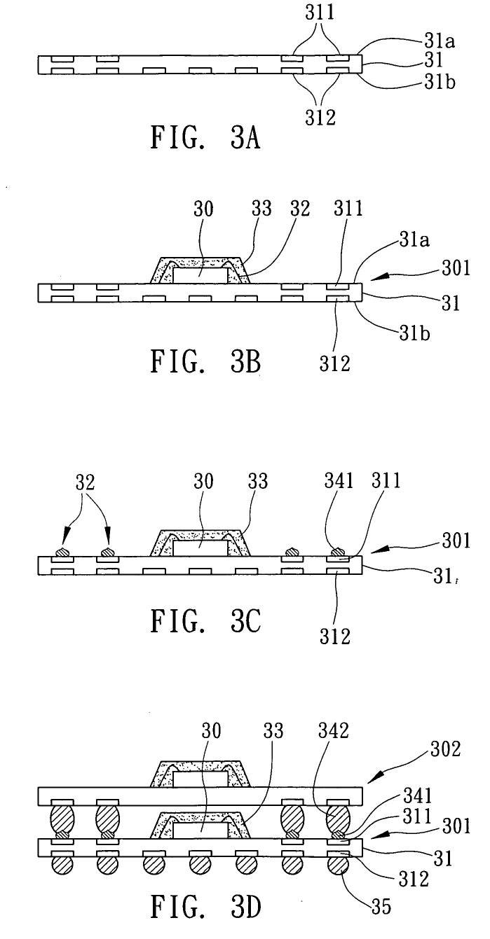

Please refer to FIGS. 3A through 3D, which are sectional view diagrams showing a stacked package structure and fabrication method thereof according to the first embodiment of the present invention.

As shown in FIGS. 3A and 3B, a substrate 31 that has a first surface 31a and an opposed second surface 31b is provided first. The substrate 31 is such as a ball grid array substrate, a plurality of stackable solder pads 311 is formed on the first surface 31a of the substrate 31, and a plurality of solder ball pads 312 is formed on the second surface 31b of the substrate 31.

Next, at least one semiconductor chip 30 is mounted on and electrically connected to the first surface 31a of the substrate 31, wherein the semiconductor chip 30 can be electrically connected to the substrate 31 via bonding wires 32 as shown in the Figures or by means of flip chip (not shown in the Figures). Also, an encapsulant 33 is formed to encapsulate the semiconductor chip 30, and the stackable solder pads 311 are exposed from the encapsulant 33. Thus, a lower-layer semiconductor package 301 is fabricated.

As shown in FIG. 3C, conductive bumps 341 such as gold stud bumps are formed on all of the stackable solder pads 311 by means of wire bonding using a wire bonding machine.

As shown in FIG. 3D, a fine pitch upper-layer semiconductor package 302 is provided and the upper-layer semiconductor package 302 is mounted on the conductive bumps 341 and the stackable solder pads 311 of the lower-layer semiconductor package 301 via solder balls 342, wherein, stacking height of the solder balls 342 and the conductive bump 341 is greater than height of the encapsulant 33 of the lower-layer semiconductor package 301. Thus a stacked package structure is formed.

Further, solder balls 35 can be mounted on the solder ball pads 312 of the second surface of the substrate 31 of the lower-layer semiconductor package 301 such that the stacked package structure can be electrically connected to an external device through the solder balls 35.

Namely, when the upper-layer semiconductor package is a fine pitch semiconductor package and height of the solder balls of the upper-layer semiconductor package after collapse is smaller than height of the encapsulant of the lower-layer semiconductor package, the conductive bumps are disposed on all of the stackable solder pads on the substrate of the lower-layer semiconductor package so as to compensate for insufficient height when the upper-layer semiconductor package is mounted on the lower-layer semiconductor package via the solder balls, thereby making the solder balls effectively contact and wet on the substrate of the lower-layer semiconductor package.

By means of the foregoing fabrication method, the present invention also discloses a stacked package structure, which comprises: a lower-layer semiconductor package 301 comprising: a substrate 31, a semiconductor chip 30 electrically connected to the substrate 31, an encapsulant 33 formed on the substrate 31 for encapsulating the semiconductor chip 30, and a plurality of stackable solder pads 311 formed on surface of the substrate 31 and exposed from the encapsulant 33; conductive bumps 341 formed on at least one stackable solder pad 311 by means of wire bonding; and at least one upper-layer semiconductor package 302 mounted on the conductive bumps 341 and the stackable solder pads 311 via solder balls 342, wherein, stacking height of the solder balls 342 and the conductive bumps 341 is greater than height of the encapsulant 33 of the lower-layer semiconductor package 301.

### Second Embodiment

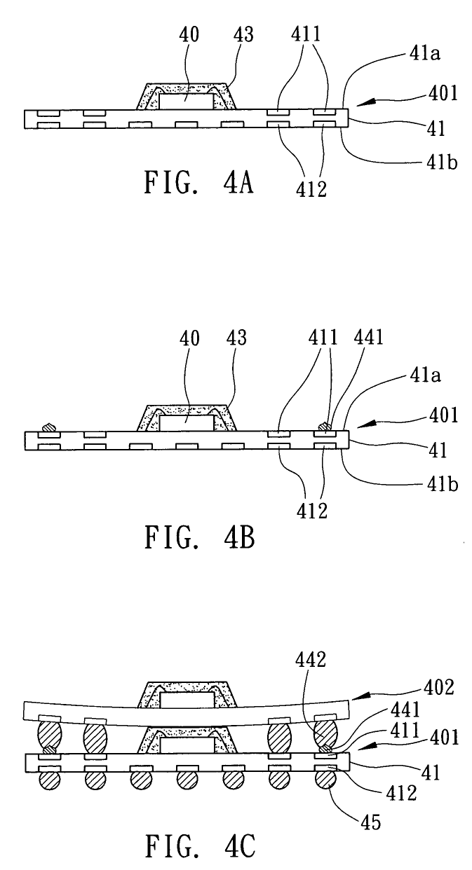

Please refer to FIGS. 4A through 4C, which are sectional view diagrams of a stacked package structure and fabrication method thereof according to the second embodiment of the present invention.

As shown in FIG. 4A, a substrate 41 that has a first surface 41a and an opposed second surface 41b is provided. The substrate is such as a ball grid array substrate, a plurality of stackable solder pads 411 is disposed on the first surface 41a of the substrate 41, and a plurality of solder ball pads 412 is disposed on the second surface 41b of the substrate 41.

Next, at least one semiconductor chip 40 is mounted on and electrically connected to the first surface 41a of the substrate 41, and an encapsulant 43 is formed to encapsulate the semiconductor chip 40 with the stackable solder pads 411 exposed from the encapsulant 43, thereby forming a lower-layer semiconductor package 401.

As shown in FIG. 4B, a plurality of conductive bumps 441 such as gold stud bumps is formed on part of the stackable solder pads 411 at periphery of the substrate 41 by means of wire bonding.

As shown in FIG. 4C, an upper-layer semiconductor package 402 that has warps is mounted on the conductive bumps 441 and stackable solder pads 411 of the lower-layer semiconductor package 401 via solder balls 442, wherein, stacking height of the solder balls 442 and the conductive bumps 441 is greater than height of the encapsulant 43 of the lower-layer semiconductor package 401. Thus a stacked package structure is fabricated.

Namely, when warp occurs to the upper-layer semiconductor package (or the lower-layer semiconductor package) due to processing stress, the conductive bumps can be selectively mounted on the stackable solder pads at periphery of the substrate so as to fill up gaps between the solder balls and the stackable solder pads at periphery of the substrate of the upper-layer and the lower-layer semiconductor packages caused by the warp, thereby making the solder balls effectively contact and wet the substrate of the lower-layer semiconductor package.

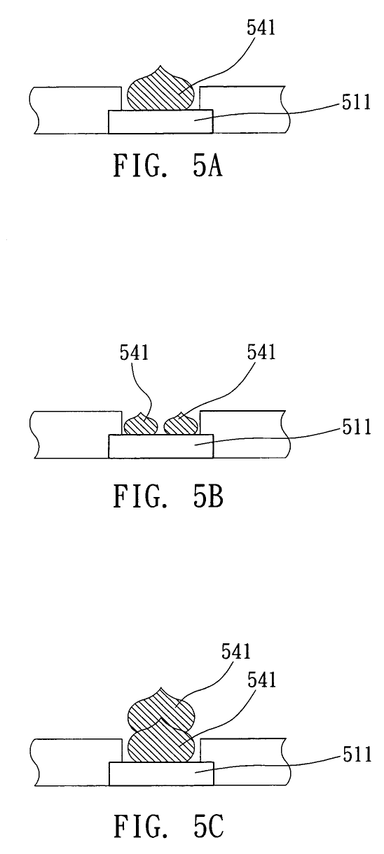

In addition, please referring to FIGS. 5A through 5C, a single conductive bump 541 can be disposed on a stackable solder pad 511 (as shown in FIG. 5A), or a plurality of conductive bumps 541 arranged in a plane can be disposed on a stackable solder pad 511 (as shown in FIG. 5B), or a plurality of conductive bumps 541 in vertically stacked configuration can be disposed on a stackable solder pad 511 (as shown in FIG. 5C). The different patterns of conductive bumps 541 can be selected according to practical fabrication need so as to achieve sufficient support area or height, thereby making the solder balls of the upper-layer semiconductor package effectively contact and wet on the substrate of the lower-layer semiconductor package.

According to the present invention, the conductive bumps are formed on at least one stackable solder pad on surface of the substrate of a lower-layer semiconductor package such that when the upper-layer and the lower-layer semiconductor packages are combined through solder balls, the conductive bumps can compensate for insufficient height caused by solder ball collapse or fill up gaps between the solder balls and the stackable solder pads of the substrate at periphery of the upper-layer and the lower-layer semiconductor packages caused by warps, thereby preventing the conventional problem of poor soldering connection. Meanwhile, the present invention overcomes the conventional drawbacks of high fabrication cost and complicated fabrication process caused by predisposing of a pre-solder material.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A fabrication method of a stacked package structure, comprising the steps of:
providing a substrate with a plurality of stackable solder pads on surface thereof, electrically connecting at least one semiconductor chip to the substrate, and forming an encapsulant to encapsulate the semiconductor chip with the stackable solder pads exposed from the encapsulant, thereby forming a lower-layer semiconductor package;
forming conductive bumps on at least one stackable solder pad by means of wire bonding; and
providing at least one upper-layer semiconductor package, and mounting the upper-layer semiconductor package on the conductive bumps and the stackable solder pads of the lower-layer semiconductor package via solder balls, wherein, stacking height of the solder balls and the conductive bump is greater than height of the encapsulant of the lower-layer semiconductor package, thus forming a stacked package structure.

2. The fabrication method of a stacked package structure of claim 1, wherein, the substrate is a ball grid array substrate, which has a first surface with a plurality of stackable solder pads disposed thereon, and an opposed second surface with a plurality of solder ball pads disposed thereon for mounting of solder balls.

3. The fabrication method of a stacked package structure of claim 1, wherein, the conductive bumps are gold stud bumps formed by wire bonding using a wire bonding machine.

4. The fabrication method of a stacked package structure of claim 1, wherein, the upper-layer semiconductor package is a fine pitch semiconductor package, height of the solder balls of the upper-layer semiconductor package after collapse is smaller than height of the encapsulant of the lower-layer semiconductor package, the conductive bumps are disposed on all of the stackable solder pads of the substrate of the lower-layer semiconductor package such that when the upper-layer semiconductor package is mounted on the lower-layer semiconductor package via the solder balls, the conductive bumps can compensate for the insufficient height caused by collapse of the solder balls.

5. The fabrication method of a stacked package structure of claim 1, wherein, when warps occur to the upper-layer semiconductor package due to processing stress, the conductive bumps can be selectively disposed on the stackable solder pads at periphery of the substrate such that gaps between the solder balls and the stackable solder pads of the substrate at periphery of the upper-layer and the lower-layer semiconductor packages caused by warps can be filled up by the conductive bumps.

6. The fabrication method of a stacked package structure of claim 1, wherein, when warps occur to the lower-layer semiconductor package due to processing stress, the conductive bumps can be selectively disposed on the stackable solder pads at periphery of the substrate such that gaps between the solder balls and the stackable solder pads of the substrate at periphery of the upper-layer and the lower-layer semiconductor packages caused by warps can be filled up by the conductive bumps.

7. The fabrication method of a stacked package structure of claim 1, wherein, one single conductive bump or a plurality of conductive bumps in a plane or vertically stacked configuration can be disposed on one stackable solder pad.

8. A stacked package structure, comprising:
a lower-layer semiconductor package comprising a substrate, at least one semiconductor chip electrically connected to the substrate, an encapsulant formed on the substrate to encapsulate the semiconductor chip, and a plurality of stackable solder pads formed on surface of the substrate and exposed from the encapsulant;
conductive bumps disposed on at least one stackable solder pad by means of wire bonding; and
at least one upper-layer semiconductor package, mounted on the conductive bumps and the stackable solder pads via solder balls, wherein, stacking height of the conductive bump and the solder balls is greater than height of the encapsulant of the lower-layer semiconductor package,

9. The stacked package structure of claim 8, wherein, the substrate is a ball grid array substrate, which has a first surface with a plurality of stackable solder pads disposed thereon, and an opposed second surface with a plurality of solder ball pads disposed thereon for mounting of solder balls.

10. The stacked package structure of claim 8, wherein, the conductive bumps are gold stud bumps formed by means of wire bonding using a wire bonding machine.

11. The stacked package structure of claim 8, wherein, the upper-layer semiconductor package is a fine pitch semiconductor package, height of the solder balls of the upper-layer semiconductor package after collapse is smaller than height of the encapsulant of the lower-layer semiconductor package, the conductive bumps are disposed on all of the stackable solder pads of the substrate of the lower-layer semiconductor package such that when the upper-layer semiconductor package is mounted on the lower-layer semiconductor package via the solder balls, the conductive bumps can compensate for the insufficient height caused by collapse of the solder balls.

12. The stacked package structure of claim 8, wherein, when warps occur to the upper-layer semiconductor package due to processing stress, the conductive bumps can be selectively disposed on the stackable solder pads at periphery of the substrate such that gaps between the solder balls and the stackable solder pads of the substrate at periphery of the upper-layer and the lower-layer semiconductor packages caused by warps can be filled up by the conductive bumps.

13. The stacked package structure of claim 8, wherein, when warps occur to the lower-layer semiconductor package due to processing stress, the conductive bumps can be selectively disposed on the stackable solder pads at periphery of the substrate such that gaps between the solder balls and the stackable solder pads of the substrate at periphery of the upper-layer and the lower-layer semiconductor packages caused by warps can be filled up by the conductive bumps.

14. The stacked package structure of claim 8, wherein one single conductive bump or a plurality of conductive bumps in a plane or vertically stacked configuration can be disposed on one stackable solder pad.
